(19) United States
(12) Patent Application Publication
(10) Pub. No.: US 2024/0136835 A1
(43) Pub. Date: Apr. 25, 2024

(54) Home Safe Charging Station Device and Method of Use Thereof

(71) Applicant: Dennis James, Oswego, NY (US)

(72) Inventor: Dennis James, Oswego, NY (US)

(21) Appl. No.: 18/181,714

(22) Filed: Mar. 10, 2023

Related U.S. Application Data
(60) Provisional application No. 63/418,194, filed on Oct. 21, 2022.

(51) Int. Cl. H02J 7/00; A62C 3/16; A62C 37/12; H05K 5/02

(52) U.S. Cl. CPC H02J 7/0044; A62C 3/16; A62C 37/12; H02J 7/00309; H05K 5/0209

(57) ABSTRACT

The present invention relates to a novel cordless power tool, electronic device, and battery charging station. The charging station is a home safe-like device having a fireproof housing for providing a power strip. The power strip includes a plurality of electric sockets for providing electric power to the tools and devices connected thereto, a fire sensor is configured to detect overheated devices or fire inside the housing, wherein a front door of the housing is automatically closed upon detecting fire. A fire link melts to release the tension of the front door allowing the door to automatically shut and thus prevents fire and smoke from coming out of the housing. In one embodiment, carbon dioxide is sprayed for extinguishing the fire inside the housing.

### CROSS-REFERENCE TO RELATED APPLICATION

The present application claims priority to, and the benefit of, U.S. Provisional Application No. 63/418,194, which was filed on Oct. 21, 2022, and is incorporated herein by reference in its entirety.

### FIELD OF THE INVENTION

The present invention relates generally to the field of power tools and electronic devices and charging tools. More specifically, the present invention relates to a novel fireproof charging station for providing a plurality of electric sockets that provides charging of batteries of tools and devices in a safe and fireproof manner. The station is in the form of a portable fireproof box and includes a fire sensor for detecting fire and a mechanism for automatically closing the door of the box in case fire, heat, or smoke is detected. The box prevents fire, heat, or smoke from coming out and thus protects homes and businesses from loss and injury. Accordingly, the present disclosure makes specific reference thereto. Nonetheless, it is to be appreciated that aspects of the present invention are also equally applicable to other like applications, devices, and methods of manufacture.

### BACKGROUND

By way of background, battery charging is one of the most fundamental requirements for working of a portable electronic device such as a smartphone, a computing device, and even portable and cordless power tools. Charging circuits of the devices are designed depending on different factors including battery chemistry, power levels, and system load. Further, the electronic devices adapt to the external current supplied to the charging circuits. However, fluctuating power supply, USB chargers, and cables may pose a severe threat while charging of the devices.

Overheated charging circuits and batteries of electronic devices and power tools during charging may pose the risk of fire. Electrical gadget chargers or cables may pose fire risks because they can severely overheat when recharged for a prolonged duration. Such fire can cause great personal loss and injuries at both homes and businesses. Individuals may not quickly find a way to escape and extinguish fire. Tool manufacturing companies are working continuously on eliminating such incidents, but even then, incidents of fire during recharging of tool and electronic devices are common across the globe and therefore, individuals desire an improved device that can prevent ire and associated damage.

Therefore, there exists a long-felt need in the art for an improved charging station for portable power tool and electronic devices. There is also a long-felt need in the art for a charging station that protects homes and businesses from fire and associated damages caused due to overheating of charging tools and devices. Additionally, there is a long-felt need in the art for a novel charging station that eliminates incidents of fire causing injuries and monetary losses. Moreover, there is a long-felt need in the art for a charging station device that contains fire within an enclosed space and automatically extinguishes fire. Further, there is a long-felt need in the art for a charging station that can recharge multiple tools, chargers, and batteries simultaneously. Finally, there is a long-felt need in the art for an improved charging station that protects individuals from personal property loss or damage caused due to recharging tools and devices.

The subject matter disclosed and claimed herein, in one embodiment thereof, comprises a fireproof home safe charging station device for safely charging a plurality of portable power tools and electronic devices. The station device further features a fireproof box like housing formed of a bottom wall, a top wall, a pair of side walls and a rear wall, a spring-loaded front door closes the housing for creating an air-free enclosure. A power strip is attached to the rear wall in the interior of the housing and includes a plurality of electric sockets for receiving charging cords of the tools or devices. The power strip has an electric cord for receiving electric supply from an external power supply such as a wall mounted AC socket. A fire sensor is arranged to the top wall inside of the housing for detecting fire, heat, or smoke inside the housing, a fire link configured to provide tension to the spring-loaded front door for keeping the front door in an open position, thereby allowing a user to access the power strip, wherein upon detecting the fire, heat, or smoke by the fire sensor, the fire link is fused to release the tension in the spring-loaded front door to automatically close the door for preventing fire, heat, or smoke releasing outside the housing.

In this manner, the fireproof home safe charging station device of the present invention accomplishes all of the forgoing objectives and provides users with a fireproof charging station to charge portable power tools. The device allows for charging in a contained manner as to avoid an overheated device that may cause a fire and protects homes and businesses from personal property loss or damage. The automatic shutoff mechanism prevents fire from spreading and closes the housing to maintain air-free enclosure.

### SUMMARY OF THE INVENTION

The following presents a simplified summary in order to provide a basic understanding of some aspects of the disclosed innovation. This summary is not an extensive overview, and it is not intended to identify key/critical elements or to delineate the scope thereof. Its sole purpose is to present some general concepts in a simplified form as a prelude to the more detailed description that is presented later.

The subject matter disclosed and claimed herein, in one embodiment thereof, comprises a fireproof home safe charging station device for safely charging a plurality of portable power tools and electronic devices. The station device further comprising a housing formed by a bottom wall, a top wall, a pair of side walls and a rear wall, a spring-loaded front door is configured to close the housing for creating an air-free or air limited enclosure, a power strip attached to a wall of an interior of the housing, the power strip includes a plurality of electric sockets for receiving charging cords of the tools or devices, the power strip has an electric cord for receiving electric supply from an external power supply, a fire sensor arranged to a wall inside of the housing, the fire sensor is configured to detect fire, heat, or smoke inside the housing, a fire link configured to provide tension to the spring-loaded front door for keeping the front door in an open position, thereby allowing a user to access the power strip, wherein upon detecting the fire, heat, or smoke by the fire sensor, the fire link is fused to release the tension in the spring-loaded front door to automatically close the door for preventing fire, heat, or smoke releasing to the outside of the housing.

In yet another embodiment, the power strip includes a power switch configured to interrupt power supply from the external power supply to the power strip upon detection of fire, heat, or smoke by the fire sensor.

In yet another embodiment, the station device detects an overheating recharging device and interrupts the power supply to the power strip.

The subject matter disclosed and claimed herein, in one embodiment thereof, comprises a fireproof charging station to charge portable power tools and electronic devices. The station includes a fire-proof box with a spring-loaded door on the front, the door is in an open state during normal operation of the station for allowing a user to access a power strip disposed inside the box, a fire sensor for detecting flame or smoke inside the box, wherein the door automatically closes upon fire, heat, or smoke detection by the fire sensor, the power strip includes a plurality of electric sockets for providing electric power to recharge portable power tools and electronic devices, a carbon dioxide generator for spraying carbon dioxide to extinguish fire inside the housing, wherein power supply to the power strip is interrupted when the fire sensor detects fire, heat, or smoke inside the box.

In another aspect of the present invention, a method of safely recharging portable power tools and electronic devices in a fireproof housing device is described. The method includes the steps of providing a fireproof housing, the housing having a door on the front configured to operate in an open state and a closed state, a fire link configured to melt when fire is detected inside the housing and close the door for switching from the open state to the closed state; connecting a power tool to a power strip positioned inside the housing; connecting the power strip to an external power supply for receiving electric power; detecting fire, heat, or smoke inside the housing while the tool is being recharged; automatically closing the door and interrupting the power supply to the power strip upon detection of the fire, heat, or smoke.

In yet another embodiment of the present invention, the method includes the step of spraying carbon dioxide inside the housing for extinguishing the fire.

In yet another embodiment, the fireproof charging station device of the present invention is easily and efficiently manufactured, marketed, and available to consumers in a cost-effective manner and is easily installed and used by users.

Numerous benefits and advantages of this invention will become apparent to those skilled in the art to which it pertains upon reading and understanding of the following detailed specification.

To the accomplishment of the foregoing and related ends, certain illustrative aspects of the disclosed innovation are described herein in connection with the following description and the annexed drawings. These aspects are indicative, however, of but a few of the various ways in which the principles disclosed herein can be employed and are intended to include all such aspects and their equivalents. Other advantages and novel features will become apparent from the following detailed description when considered in conjunction with the drawings.

### BRIEF DESCRIPTION OF THE DRAWINGS

The description refers to provided drawings in which similar reference characters refer to similar parts throughout the different views, and in which:

FIG. 1 illustrates a perspective view of one potential embodiment of a home safe charging station device (i.e., charging station box) of the present invention in accordance with the disclosed architecture;

FIG. 2 illustrates a perspective view of the home safe box charging station device of the present invention in a closed state in accordance with the disclosed architecture;

FIG. 3 illustrates a flow diagram depicting a process of operation of the charging station device of the present invention in accordance with the disclosed architecture; and

FIG. 4 illustrates a schematic view showing the connection of the internal components of the charging station device of the present invention for interrupting a power supply and closing a front door when fire is detected in accordance with the disclosed architecture.

### DETAILED DESCRIPTION OF THE PRESENT INVENTION

The innovation is now described with reference to the drawings, wherein like reference numerals are used to refer to like elements throughout. In the following description, for purposes of explanation, numerous specific details are set forth in order to provide a thorough understanding thereof. It can be evident, however, that the innovation can be practiced without these specific details. In other instances, well-known structures and devices are shown in block diagram form in order to facilitate a description thereof. Various embodiments are discussed hereinafter. It should be noted that the figures are described only to facilitate the description of the embodiments. They are not intended as an exhaustive description of the invention and do not limit the scope of the invention. Additionally, an illustrated embodiment need not have all the aspects or advantages shown. Thus, in other embodiments, any of the features described herein from different embodiments can be combined.

As noted above, there is a long-felt need in the art for an improved charging station for portable power tools, electronic devices, and battery chargers. There is also a long-felt need in the art for a charging station that protects homes and businesses from fire and associated damages caused due to overheating of charging tools, devices, and/or batteries. Additionally, there is a long-felt need in the art for a novel charging station that eliminates incidents of fire causing injuries and monetary losses. Moreover, there is a long-felt need in the art for a charging station device that contains fire within an enclosed space and automatically extinguishes fire therein. Further, there is a long-felt need in the art for a charging station that can recharge multiple tools, chargers, and batteries simultaneously. Finally, there is a long-felt need in the art for an improved charging station that protects individuals from personal property loss or damage caused due to recharging tools, devices, and/or batteries.

The present invention, in one exemplary embodiment, is a method of safely recharging portable power tools and electronic devices in a fireproof housing device. The method includes the steps of providing a fireproof housing, the housing having a door on the front configured to operate in an open state and a closed state, a fire link configured to melt when fire is detected or encountered inside the housing and close the door for switching from the open state to the closed state; connecting a power tool to a power strip positioned inside the housing; connecting the power strip to an external power supply for receiving electric power; detecting fire, heat, or smoke inside the housing while the tool is being recharged; automatically closing the door and interrupting the power supply to the power strip.

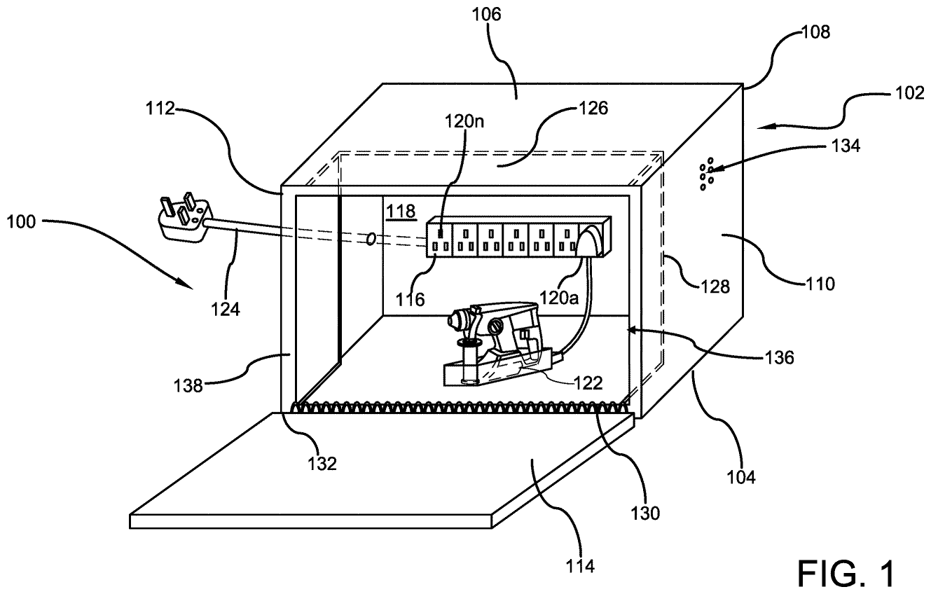

Referring initially to the drawings, FIG. 1 illustrates a perspective view of one potential embodiment of a home safe charging station device of the present invention in accordance with the disclosed architecture. The home safe charging station device 100 of the present invention is designed as a fireproof charging station for safely charging cordless tools, portable electronic devices, battery chargers, and more and for protecting homes and businesses from personal property loss or damage due to potential fire while charging batteries and chargers. The device 100 is portable, lightweight, and can be used at home, in businesses, and in public places.

More specifically, the charging station device 100 includes a housing 102 in the shape of a generally square or rectangular box formed of a bottom wall 104, a top wall 106, a rear wall 108, and a pair of side walls 110, 112. The housing 102 is configured to provide storage space for keeping a plurality of electronic devices and tools for charging wherein a pivotable spring-loaded front door 114 of the device 100 is configured to remain open during normal operation of the device 100 for charging batteries of the devices stored inside the device 100. The front door 114 automatically closes in case a fire or excessive heat is detected or encountered inside the housing 102 as described in detail later in the disclosure. A power strip 116 is attached on the inner surface 118 of, for example, the rear wall 108 and is configured to provide a plurality of electric sockets 120a-n for plugging in one or more electronic devices and tools (an exemplary portable tool 122 is shown and is connected to the socket 120a) for battery recharging. The electric sockets 120a-n can be of multiple types such as two prong or three prong (i.e., grounding receptacle) for accommodating different types of devices for recharging.

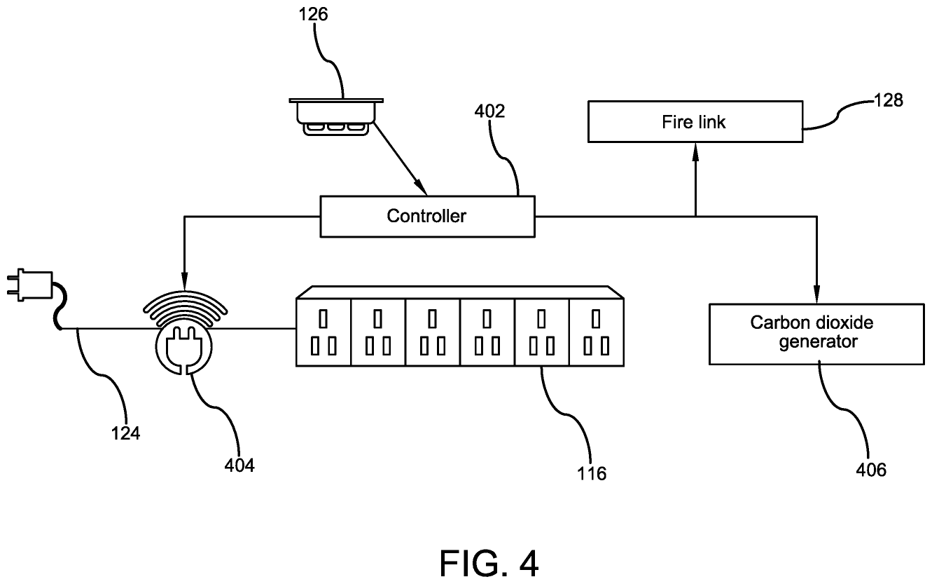

The power strip 116 is connected to an external power cord 124, which can be attached to any external power supply such as a wall mounted power socket for providing electric power to the power strip 116, which in turn is provided to one or more connected portable tools and devices. A switch is also disposed in the power strip 116 to automatically disable power supply to the power strip 116 in case of a fire or heat detection inside the charging station device 100 as described in FIG. 4. The power strip 116 is easily accessible to a user for plugging in an electronic device for recharging and further, the device 100 is portable and can be placed on any surface as per a preference of a user.

It is a common occurrence for charging tools and devices to catch fire due to faulty batteries, faulty chargers, faulty cords, and more. In many cases, fire can be caused due to short circuit as well. A fire sensor or heat/smoke detector 126 connected to a fusible fire link 128 is disposed inside the housing 102 and for example, on the top wall 106 of the interior of the housing 102. The fire sensor or heat/smoke detector 126 is configured to detect any fire, heat, or smoke inside the housing 102 while the device 100 is active. The fire link 128 is connected to the spring-loaded door 114 and maintains the required tension for holding the door 114 open. When the fire sensor or heat/smoke detector 126 detects or encounters the fire inside the housing 102, the fire link 128 melts or burns to remove the tension (i.e., release) and the front door 114 is automatically actuated and closed. A plurality of springs 130 are positioned at the bottom layer 132 of the door 114 are released upon burning or melting of the fire link 128 and automatically closes the door 114. The housing 102 and the front door 114 are made of fire-proof and explosion-proof material such as fiberglass silicone and can accommodate a plurality of electronic devices and portable tools.

The power strip 116 and the inside of the housing 102 are fire resistant and do not melt or catch fire when the door 114 is closed. Further, the device 100 has a plurality of holes 134 on the side walls 110, 112 such that pressurized carbon dioxide is sprayed inside the housing 102 to extinguish the fire when the fire sensor or heat/smoke detector 126 detects the fire, heat, or smoke. A carbon dioxide store is embedded in the home safe charging station device 100 as illustrated in FIG. 4. In some of the embodiments, the device 100 may not have the plurality of holes 134 and the carbon dioxide store. Along the front edge 136 of the housing 102, a sealant material 138 is disposed for providing effective air-proof, or air restricted, enclosure inside the housing 102 when the front door 114 is closed. The front door 114 does not allow any of the fire and the smoke to come out of the housing 102 and thus helps homes and businesses from accidental fire.

The fire sensor or heat/smoke detector 126 in the preferred embodiment is an electromechanical heat detector made of a bimetallic strip that expands upon detecting high temperature. A threshold temperature is reached to completely expand the strip as a result of a fire or a flame being detected or encountered inside the housing 102. Alternatively, in some embodiments, the fire sensor or heat/smoke detector 126 can be an electronic heat detector configured to change its resistance with change in temperature. In some embodiments, an overheated or elevated temperature can be detected to interrupt power supply and automatically closing of the front door 114.

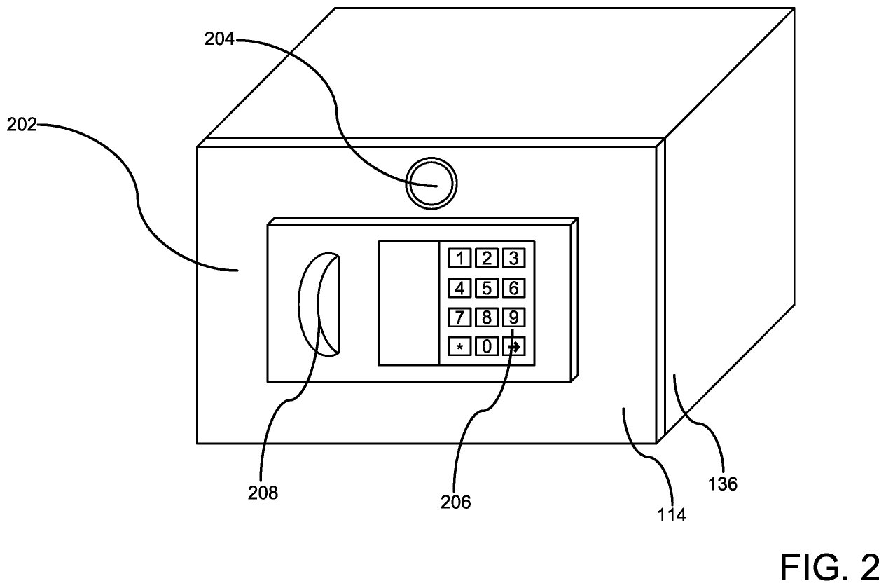

FIG. 2 illustrates a perspective view of the home safe box charging station device of the present invention in a closed state in accordance with the disclosed architecture. The device 100 automatically closes when fire, heat, or smoke is detected by the fire sensor or heat/smoke detector 126 resulting in closing of the fusible link 128 resulting in release of tension holding the front door 114. The device 100 when closed creates an air free, or air restricted, chamber inside the housing 102 and does not let fire, heat, or smoke to be expelled out of the housing 102. Further, the carbon dioxide can be sprayed automatically or alternatively manually inside the housing 102 for extinguishing the fire.

The door 114 when manually closed by a user such as in a situation when not being used for recharging devices, the fusible link 128 does not burn or melt. In some embodiments of the present invention, the door 114 always remains open until the fire is detected by the fire sensor or heat/smoke detector 126. Alternatively, the door 114 can be manually closed by a user without causing spraying of carbon dioxide and fusing of the link 128. The front surface 202 of the housing 102 has a push button 204 for manually opening and closing the door 114 and a keypad 206 for securing access of the device 100. The keypad 206 can be programmed to provide an authorized PIN for opening the front door 114 to access the power strip 116. For easy handling of the door 114, a handle 208 is disposed on the exterior surface 202 of the door 114.

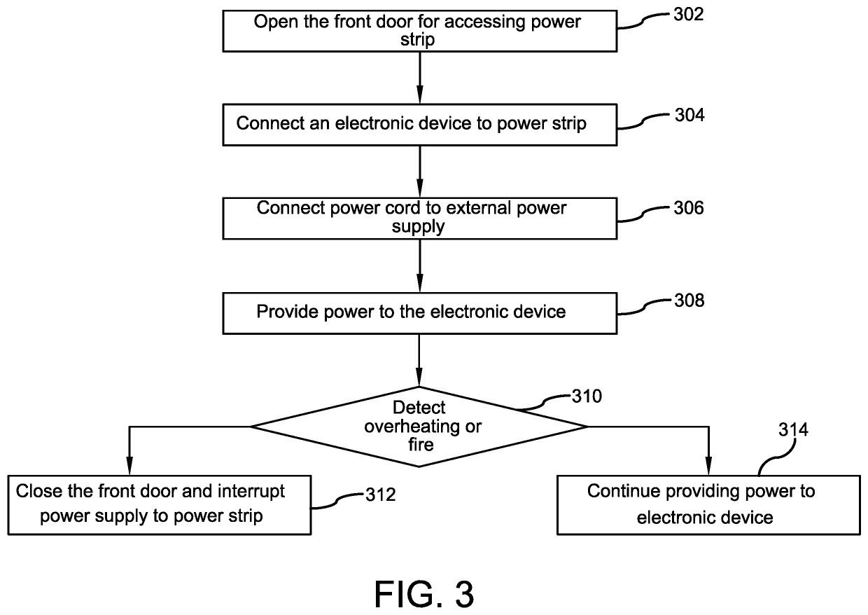

FIG. 3 illustrates a flow diagram depicting a process of operation of the charging station device of the present invention in accordance with the disclosed architecture. Initially, the front door is opened for accessing the inside of the housing and the power strip arranged on the rear wall of the housing (Step 302). In some embodiments, the door can be opened by default. Then, one or more electronic devices, tools, and/or battery chargers are positioned inside the housing and are connected to one of the electric sockets of the power strip for recharging of the battery thereof (Step 304). Thereafter, the power cord of the device is connected to the external power supply for providing power to the electric sockets of the power strip (Step 306). The power strip has a regulatory mechanism of countering fluctuating power supply from the external power socket and therefore, provides a uniform power supply to the connected devices.

After the device 100 is activated, the electric supply is provided to the connected electronic devices and tools (Step 308). When the electronic devices are recharged using the power strip, the fire sensor continuously detects presence of fire, heat, or smoke inside the housing (Step 310). If the fire sensor detects the flame, heat, or smoke, then, the fire link 128 is fused and the front door of the station device 100 is automatically closed (Step 312). The front door creates a vacuum inside the housing for preventing the flame from expelling out of the housing 102 and thus protecting users and surrounding areas. In situations where no fire, heat, or smoke is detected, then, electric power is continuously provided to the connected tools and devices for recharging while the front door remains open (Step 314).

FIG. 4 illustrates a schematic view showing the connection of the internal components of the charging station device 100 of the present invention for interrupting power supply and closing the front door when fire is detected in accordance with the disclosed architecture. When fire, heat, or smoke is detected by the fire sensor, heat detector, or smoke detector 126, an instruction signal is sent to the controller 402 disposed inside the housing 102 wherein the instruction signal indicates presence of a fire, heat, or smoke inside the housing. Based on the instruction signal received from the sensor 126, the controller 402 sends a second instruction signal to the power switch 404 for interrupting power supply to the power strip 116 from the external power supply. The power switch 404 closes the electric connection between the cord 124 and the power strip 116 and thus, prevents the chances of fire due to continuous supply of electric power.

The fire link 128 melts for releasing the tension of the torsional springs to automatically close the front door. Simultaneously, carbon dioxide is sprayed inside the housing 102 from the carbon dioxide generator 406 upon receiving a third instruction signal from the controller 402.

Certain terms are used throughout the following description and claims to refer to particular features or components. As one skilled in the art will appreciate, different persons may refer to the same feature or component by different names. This document does not intend to distinguish between components or features that differ in name, but not structure or function. As used herein “charging station device”, “home safe charging station device”, “charging station device”, and “device” are interchangeable and refer to the home safe charging station device 100 of the present invention.

Notwithstanding the forgoing, the home safe charging station device 100 of the present invention can be of any suitable size and configuration as is known in the art without affecting the overall concept of the invention, provided that it accomplishes the above-stated objectives. One of ordinary skill in the art will appreciate that the home safe charging station device 100 as shown in the FIGS. are for illustrative purposes only, and that many other sizes and shapes of the home safe charging station device 100 are well within the scope of the present disclosure. Although the dimensions of the home safe charging station device 100 are important design parameters for user convenience, the home safe charging station device 100 can be of any size that ensures optimal performance during use and/or that suits the user's needs and/or preferences.

Various modifications and additions can be made to the exemplary embodiments discussed without departing from the scope of the present invention. While the embodiments described above refer to particular features, the scope of this invention also includes embodiments having different combinations of features and embodiments that do not include all of the described features. Accordingly, the scope of the present invention is intended to embrace all such alternatives, modifications, and variations as fall within the scope of the claims, together with all equivalents thereof.

What has been described above includes examples of the claimed subject matter. It is, of course, not possible to describe every conceivable combination of components or methodologies for purposes of describing the claimed subject matter, but one of ordinary skill in the art may recognize that many further combinations and permutations of the claimed subject matter are possible. Accordingly, the claimed subject matter is intended to embrace all such alterations, modifications and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

What is claimed is:

1. A charging station device comprising:
a charging station having a housing including a bottom wall, a top wall, a rear wall, a pair of side walls, and a pivotable spring-loaded front door;
wherein said housing providing storage space for keeping a plurality of rechargeable electronic devices therein;
a heat detector connected to a fusible fire link disposed inside said housing;
wherein said heat detector configured to detect heat inside said housing;
wherein said heat detector actuates said fusible fire link when said heat detector detects an elevated temperature;
wherein said fusible fire link is connected to said pivotable spring-loaded front door; and
further wherein said fusible fire link melts in response to the elevated temperature and releases said pivotable spring-loaded front door to close said pivotable spring-loaded front door.

2. The charging station device of claim 1, wherein said pivotable spring-loaded front door having a plurality of springs positioned at a bottom layer of said pivotable spring-loaded front door are released upon the melting of said fusible fire link to automatically close said pivotable spring-loaded front door.

3. The charging station device of claim 2, wherein said housing having an interior material comprising fiberglass silicone.

4. The charging station device of claim 2, wherein said pivotable spring-loaded front door to remain open during normal operation of said charging station for charging said plurality of rechargeable electronic devices.

5. The charging station device of claim 4, wherein said housing having a power strip mounted to one of said walls on an inside of said housing.

6. The charging station device of claim 5, wherein said power strip having a plurality of electric sockets for plugging said plurality of rechargeable electronic devices.

7. The charging station device of claim 6, wherein said housing is a generally rectilinear box.

8. The charging station device of claim 6, wherein said power strip connected to an external power cord for attaching to an external power supply.

9. The charging station device of claim 6 further comprising a heat sensitive switch disposed in said power strip to automatically disable the power supply to said power strip in case of heat detection inside said housing.

10. A charging station device comprising:
a charging station having a housing including a bottom wall, a top wall, a rear wall, a pair of side walls, and a pivotable spring-loaded front door;
wherein said housing providing an interior space for keeping a plurality of rechargeable electronic devices therein;
a fire detector connected to a fusible fire link disposed inside said housing;
a carbon dioxide store is embedded in said housing;
wherein said fire detector configured to detect a fire inside said housing;
wherein said fire detector actuates said fusible fire link when said fire detector detects the fire;
wherein said fusible fire link is connected to said pivotable spring-loaded front door; and
further wherein said fusible fire link melts in response to the fire and releases said pivotable spring-loaded front door to close said pivotable spring-loaded front door and to spray said carbon dioxide automatically inside said housing for extinguishing the fire.

11. The charging station device of claim 10, wherein said housing having an interior material comprising fiberglass silicone.

12. A charging station device comprising:
a charging station having a housing including a plurality of walls and a pivotable spring-loaded front door pivotally connected to at least one wall for selectively opening and closing said housing;
wherein said housing providing an interior space for keeping a plurality of rechargeable electronic devices therein;
a detector connected to a fusible link disposed inside said housing;
wherein said detector selected from a group consisting of a heat detector, a smoke detector, and a fire detector;
wherein said detector configured to detect at least one of heat, smoke, and fire inside said housing;
wherein said detector actuates said fusible link when said detector detects the heat, the smoke, or the fire;
wherein said fusible link is connected to said pivotable spring-loaded front door; and
further wherein said fusible link actuates in response to the heat, the smoke, or the fire and releases said pivotable spring-loaded front door to close said pivotable spring-loaded front door.

13. The charging station device of claim 12 further comprising a carbon dioxide store embedded in said housing, wherein said fusible link actuates in response to the heat, the smoke, or the fire to spray said carbon dioxide automatically inside said housing for extinguishing the fire.

14. The charging station device of claim 12, wherein said pivotable spring-loaded front door to remain open during normal operation of said charging station for charging said plurality of rechargeable electronic devices.

15. The charging station device of claim 12, wherein said housing having a power strip mounted to one of said walls on an inside of said housing.

16. The charging station device of claim 15, wherein said power strip having a plurality of electric sockets for plugging said plurality of rechargeable electronic devices.

17. The charging station device of claim 12, wherein said housing is a generally rectilinear box.

18. The charging station device of claim 16, wherein said power strip connected to an external power cord for attaching to an external power supply.

19. The charging station device of claim 18 further comprising a heat sensitive switch disposed in said power strip to automatically disable the power supply to said power strip in case of heat detection inside said housing.

20. The charging station device of claim 12, wherein said fusible link is a bimetallic strip that expands upon detection of the heat, the smoke, or the fire.
